(19) United States
(12) Patent Application Publication
(10) Pub. No.: US 2026/0242240 A1
(43) Pub. Date: Aug. 20, 2026

(54) UNCONVENTIONAL THERMOELECTRIC MATERIAL AND PREPARATION METHOD THEREOF

(71) Applicant: SOUTHERN UNIVERSITY OF SCIENCE AND TECHNOLOGY, Shenzhen, Guangdong (CN)

(72) Inventors: Wenqing ZHANG, Shenzhen (CN); Tao FENG, Shenzhen (CN); Yurong RUAN, Shenzhen (CN); Bing WEN, Shenzhen (CN); Weishu LIU, Shenzhen (CN)

(73) Assignee: SOUTHERN UNIVERSITY OF SCIENCE AND TECHNOLOGY, Shenzhen, Guangdong (CN)

(21) Appl. No.: 19/137,014

(22) PCT Filed: Jan. 13, 2025
(86) PCT No.: PCT/CN2025/072063

§ 371 Date: Jun. 9, 2025

(30) Foreign Application Priority Data
Dec. 9, 2024 (CN) 202411801531.0

(51) Int. Cl. C01G 49/00; H10N 10/01; H10N 10/853

(52) U.S. Cl. CPC C01G 49/009; H10N 10/01; H10N 10/853; C01P 2002/50; C01P 2002/54; C01P 2002/72; C01P 2006/32; C01P 2006/40

(57) ABSTRACT

An unconventional thermoelectric material and a preparation method thereof. The unconventional thermoelectric material has the chemical formula of TiFeₓRu_{y}Cu_{z}Sb, where x, y, z are molecular weights of Fe, Ru, and Cu in the chemical formula, 1<x+y+z<2, x and z are not 0. The unconventional thermoelectric material TiFeₓRu_{y}Cu_{z}Sb (1<x+y+z<2) exhibits excellent thermoelectric performance, which has a Seebeck coefficient that exceeds 180 μV/K within a certain temperature range, and a figure of merit reaches 1.2 at 875 K. In the temperature range of 14 K to 650 K, the resistivity of TiFeₓRu_{y}Cu_{z}Sb presents a strict linear temperature dependence, breaking through the Mott-Ioffe-Regel limit, and exhibiting non-quasiparticle bad metal transmission characteristics. This unique transmission characteristic and high thermoelectric performance result from complex electronic structure and correlation interaction, including spin and valence state fluctuations, inside TiFeₓRu_{y}Cu_{z}Sb. These characteristics enable TiFeₓRu_{y}Cu_{z}Sb to more efficiently convert thermal energy into electrical energy during thermoelectric conversion process.

### FIELD

The present disclosure relates to the field of thermoelectric materials, and in particular to an unconventional thermoelectric material and a preparation method thereof.

### BACKGROUND

Thermoelectric technology enables a direct conversion between thermal energy and electrical energy, and holds great potential for applications in fields such as deep-space exploration, waste heat recovery, and solid-state refrigeration. The thermoelectric effect was first discovered in metals by Seebeck in 1822. In the 1950s, Ioffe proposed using figure-of-merit (zT=S²σT/κ, where S is Seebeck coefficient, o is electrical conductivity, T is temperature, and k is thermal conductivity) as a guiding parameter. Since then, research has focused primarily on semiconductor-based thermoelectric materials. By tuning the transport properties of effective electrons or holes in heavily doped narrow-bandgap semiconductors (e.g., Bi₂Te₃, GeTe, CoSb₃, SnSe, Mg₃Sb₂), particularly through modulation of the density of electronic states, the thermoelectric performance has been significantly enhanced.

In addition, thermoelectric effects have also been observed at low temperatures in strongly correlated electron systems, such as unconventional superconductors and heavy fermion. However, the practical value of such materials is limited due to their poor performance. For example, superconductor Bi₂Sr₂CaCu₂O_{8+δ} exhibits a maximum thermopower of only 5.5 μV/K near the superconducting transition temperature, with a zT value as low as 1.5×10⁻⁵. The iron-based superconductor LaFeAsO_{0.84} has a Seebeck coefficient of −86 μV/K at 125 K with a zT value of 0.061. Heavy fermion systems based on Yb and Ce show a thermopower of approximately 100 μV/K at low temperatures with a zT value of 0.11. The electrical transport properties of these strongly correlated systems cannot be described using quasiparticles within the Fermi liquid framework, and thus these materials are referred to as unconventional thermoelectric materials.

Accordingly, as referred to in the present disclosure, unconventional thermoelectric materials are defined as materials in which quasiparticles do not exist during non-Fermi liquid (NFL) transport, and the carrier scattering is predominantly governed by dynamic spin and valence fluctuations arising from multi-body electronic correlations. Among all known unconventional thermoelectric materials, maintaining high thermopower at elevated temperatures remains a major challenge, resulting in a maximum zT value typically below 0.3. This significantly limits the development and practical application of the unconventional thermoelectric materials.

### SUMMARY

In view of the above-mentioned deficiencies in the prior art, the present disclosure provides an unconventional thermoelectric material and a preparation method thereof, so as to solve the problem that the existing unconventional thermoelectric materials are difficult to maintain high thermopower at elevated temperatures.

The technical solution adopted by the present disclosure to solve the above technical problems is as follows:

According to a first aspect of the present disclosure, an unconventional thermoelectric material is provided, and a chemical formula of the unconventional thermoelectric material is TiFeₓRu_{y}Cu_{z}Sb, where x, y, z are molecular weights of Fe, Ru, and Cu in the chemical formula, respectively, 1<x+y+z<2, and x and z are not 0.

Further, the chemical formula of the unconventional thermoelectric material is one of TiFe_{0.68}Ru_{0.01}Cu_{0.38}Sb, TiFe_{0.68}Ru_{0.02}Cu_{0.4}Sb, TiFe_{0.68}Ru_{0.03}Cu_{0.42}Sb, TiFe_{0.68}Cu_{0.36}Sb, TiFe_{0.69}Cu_{0.38}Sb, TiFe_{0.7}Cu_{0.4}Sb, and TiFe_{0.75}Cu_{0.5}Sb.

Further, a Seebeck coefficient of the unconventional thermoelectric material is greater than 180 μV/K, and a zT value of the unconventional thermoelectric material is greater than 1.0.

A second aspect of the present disclosure provides a method for preparing the above-mentioned unconventional thermoelectric material, the preparation method includes following steps:
weighing raw materials;
processing the raw materials with arc-melting treatment, ball milling treatment and spark plasma sintering treatment sequentially, to obtain the unconventional thermoelectric material.

Further, steps of processing the raw materials with arc-melting treatment include: placing the weighed raw materials on a water-cooled copper hearth under inert gas protection, setting a melting current to 50-120 mA and a melting time to 5-40 s, completing the arc-melting to obtain an alloy ingot.

Further, during the arc-melting treatment, a raw material of Sb is added to the water-cooled copper hearth to compensate for a weight loss due to high vapor pressure.

Further, after each arc-melting, the alloy ingot is turned over and re-melted for 2-8 times.

Further, steps of the ball milling treatment include: ball milling the alloy ingot at a rotation speed of 1400-2000 r/min for 6-120 minutes to obtain alloy powder.

Further, the ball milling treatment is carried out under inert gas protection.

Further, steps of the spark plasma sintering treatment include: spark plasma sintering the alloy powder at a temperature of 600-800° C. and a pressure of 30-60 MPa for 2-15 minutes.

### Beneficial Effects

The present disclosure provides an unconventional thermoelectric material and a preparation method thereof. The unconventional thermoelectric material TiFeₓRu_{y}Cu_{z}Sb (1<x+y+z<2, x and z are not 0) provided by the present disclosure exhibits excellent thermoelectric performance, and the Seebeck coefficient exceeds 180 μV/K within a certain temperature range, and the figure of merit (zT) can reach 1.2 at 875 K. In the temperature range of 14 K to 650 K, the resistivity of TiFeₓRu_{y}Cu_{z}Sb presents a strict linear temperature dependence, breaking through the Mott-Ioffe-Regel (MIR) limit, and exhibiting non-quasiparticle bad metal transmission characteristics. This unique transmission characteristic and high thermoelectric performance are resulted from the complex electronic structure and correlation interaction, including spin and valence state fluctuations, inside TiFeₓRu_{y}Cu_{z}Sb. These characteristics enable TiFeₓRu_{y}Cu_{z}Sb to more efficiently convert thermal energy into electrical energy during the thermoelectric conversion process, thereby improving energy utilization efficiency.

The preparation method of the present disclosure adopts conventional arc-melting, mechanical alloying and spark plasma sintering technologies, which are mature and reliable, have relatively simple equipment requirements, and are easy to operate and control. Compared with traditional complex preparation process, the preparation method of the present disclosure does not require special equipment or complex operation procedures, reduces production costs, improves production efficiency, is conducive to large-scale production, and provides possibilities for the industrial application of unconventional thermoelectric materials.

### BRIEF DESCRIPTION OF THE DRAWINGS

FIG. 1 is an XRD diagram of the thermoelectric materials prepared in embodiments 1-7 according to the present disclosure.

FIG. 2 is a graph showing resistivity versus temperature curves of the thermoelectric materials prepared in embodiments 1-6 according to the present disclosure.

FIG. 3 is a graph showing Seebeck coefficient and zT value versus temperature curves of the thermoelectric materials prepared in embodiments 1 to 4 according to the present disclosure and other thermoelectric materials.

### DETAILED DESCRIPTION OF EMBODIMENTS

The present disclosure provides an unconventional thermoelectric material and a preparation method thereof. To make the purpose, technical solution and effect of the present disclosure clearer and more specific, the present disclosure is further described in detail below. It should be understood that the embodiments described herein are only used to explain the present disclosure and are not intended to limit the present disclosure.

An embodiment of the present disclosure provides an unconventional thermoelectric material, the chemical formula of the unconventional thermoelectric material is TiFeₓRu_{y}Cu_{z}Sb, in which x, y, and z are molecular weights of Fe, Ru, and Cu in the chemical formula, respectively, 1<x+y+z<2, and x and z are not 0.

The unconventional thermoelectric material TiFeₓRu_{y}Cu_{z}Sb (1<x+y+z<2, x and z are not 0) provided by the present disclosure exhibits excellent thermoelectric performance, having a Seebeck coefficient exceeds 180 μV/K within a certain temperature range, and a figure of merit (zT) reaches 1.2 at 875 K. In the temperature range of 14 K to 650 K, a resistivity of TiFeₓRu_{y}Cu_{z}Sb shows a strict linear temperature dependence, breaking through the Mott-Ioffe-Regel (MIR) limit, and exhibiting non-quasiparticle bad metal transmission characteristics. The unique transmission characteristic and high thermoelectric performance are due to the complex electronic structure and correlation interaction, including spin and valence state fluctuations, inside TiFeₓRu_{y}Cu_{z}Sb. These characteristics enable TiFeₓRu_{y}Cu_{z}Sb to more efficiently convert thermal energy into electrical energy during the thermoelectric conversion process, thereby improving energy utilization efficiency.

In some embodiments, the chemical formula of the unconventional thermoelectric material is one of TiFe_{0.68}Ru_{0.01}Cu_{0.38}Sb, TiFe_{0.68}Ru_{0.02}Cu_{0.4}Sb, TiFe_{0.68}Ru_{0.03}Cu_{0.42}Sb, TiFe_{0.68}Cu_{0.36}Sb, TiFe_{0.69}Cu_{0.38}Sb, TiFe_{0.7}Cu_{0.4}Sb, and TiFe_{0.75}Cu_{0.5}Sb.

In some embodiments, the unconventional thermoelectric material has a Seebeck coefficient greater than 180 μV/K and a zT value greater than 1.0.

The present disclosure provides a preparation method for the above-mentioned unconventional thermoelectric material, and the preparation method includes following steps:
weighing raw materials;
processing the raw materials with arc-melting treatment, ball milling treatment and spark plasma sintering treatment sequentially, to obtain the unconventional thermoelectric material.

The preparation method of the present disclosure adopts conventional arc-melting, mechanical alloying and spark plasma sintering technologies, which are mature and reliable, have relatively simple equipment requirements, and are easy to operate and control. Compared with the traditional complex preparation process, the preparation method of the present disclosure does not require special equipment and complex operation procedures, reduces production costs, improves production efficiency, and is conducive to large-scale production, thereby providing possibilities for the industrial application of unconventional thermoelectric materials.

In some embodiments, steps of processing the raw materials with arc-melting treatment include: placing the weighed raw materials on a water-cooled copper hearth under inert gas protection, setting a melting current to 50-120 mA and a melting time to 5-40 s, arc-melting each side of the sample 2-8 times to complete the arc-melting and obtain an alloy ingot.

When the melting current is too small, the time is too short, or the number of arc-melting is too limited, above five elements cannot be completely melted together. When the melting current is too large, the time is too long, or the number of arc-melting is too large, the Sb element may volatilize too much and affect final composition.

In some embodiments, steps of processing the raw materials with arc-melting treatment include: placing the weighed raw materials on the water-cooled copper hearth under inert gas protection, setting a melting current to 80 mA and a melting time to 20 s, arc-melting each side of the sample 5 times to complete the arc-melting and obtain the alloy ingot.

In some embodiments, during the arc-melting treatment, a raw material of Sb is added to the water-cooled copper hearth to compensate for a weight loss due to the high vapor pressure.

In some embodiments, steps of the ball milling treatment include: ball milling the alloy ingot at a rotation speed of 1400-2000 r/min for 6-120 minutes to obtain alloy powder.

If the ball mill speed is too slow or the time is too short, the melted ingot cannot be completely crushed. If the speed is too fast or the ball mill time is too long, the sample may be seriously adhered to the ball mill filling, eventually resulting in sample loss.

In some embodiments, steps of the ball milling treatment include: ball milling the alloy ingot at a rotation speed of 1725 r/min for 24 minutes to obtain alloy powder.

In some embodiments, the ball milling process is performed under inert gas protection.

In some embodiments, steps of the spark plasma sintering treatment include: spark plasma sintering the alloy powder at a temperature of 600-800° C. and a pressure of 30-70 MPa for 2-15 minutes.

If the sintering temperature is too low, the pressure is too small, or the time is too short, the density of the sample may not be guaranteed, thus affecting the electrical properties of the sample. If the sintering temperature is too high, the pressure is too high, or the time is too long, the Cu ions may flow, changing the original composition of the sample and affecting the thermoelectric properties.

In some preferred embodiments, steps of the spark plasma sintering treatment include: spark plasma sintering the alloy powder at a temperature of 700° C. and a pressure of 50 MPa for 5 minutes.

The technical solutions in the embodiments of the present disclosure are described clearly and completely below. Obviously, the embodiments are only part of the embodiments of the present disclosure, not all of the embodiments, and are only for illustrating the present disclosure but not limiting the present disclosure. Based on the embodiments of the present disclosure, all other embodiments obtained by those skilled in the art without creative work are within the scope of protection of the present disclosure.

### Embodiment 1

The raw materials were prepared with the composition of TiFe_{0.68}Cu_{0.38}Sb, and an alloy ingot was prepared by arc-melting: the arc-melting treatment was carried out on a water-cooled copper hearth under Ar protective atmosphere, the arc-melting current was 80 mA, and the time was 20 s. After one arc-melting was completed, the ingot was turned over and re-melted four times, the uniformity was checked and an appropriate amount of additional Sb was added, and the amount of addition was adjusted according to the actual situation.

During ball milling, the alloy ingot was placed in a stainless steel ball milling jar and was ball milled using a SPEX 8000 M mixer in an Ar atmosphere glove box. According to the characteristics of TiFe_{0.68}Ru_{0.01}Cu_{0.38}Sb, the ball milling speed was set to 1725 r/min, and 2 large stainless steel balls and 4 small stainless steel balls were added to ensure that the alloy powder achieved the ideal particle size and uniformity.

In the sintering step, the ball-milled powder was loaded into a graphite mold with an inner diameter of 12.7 mm and subjected to spark plasma sintering (SPS) in the glove box. The sintering temperature was set to 700° C., the pressure was 50 MPa, and the time was 5 minutes. During this treatment, the stability of the sintering temperature and pressure was strictly controlled to ensure that the formed material was in a good crystal structure.

The resistivity and Seebeck coefficient were tested using professional testing equipment and methods within the corresponding temperature range. The results obtained were consistent with the material performance characteristics described in the present disclosure. That is, within a wide temperature range, the resistivity shows a linear temperature dependence, the Seebeck coefficient shows a maximum value of 236 μV/K, and the zT value reaches a maximum of 1.2.

### Embodiment 2

The raw materials were prepared with the composition of TiFe_{0.68}Ru_{0.01}Cu_{0.38}Sb, and an alloy ingot was prepared by arc-melting: the arc-melting treatment was carried out on a water-cooled copper hearth under Ar protective atmosphere, the arc-melting current was 80 mA, and the time was 20 s. After one arc-melting was completed, the ingot was turned over and re-melted four times, the uniformity was checked and an appropriate amount of additional Sb was added, and the amount of addition was adjusted according to the actual situation.

During ball milling, the alloy ingot was placed in a stainless steel ball milling jar and was ball milled using a SPEX 8000 M mixer in an Ar atmosphere glove box. According to the characteristics of TiFe_{0.68}Ru_{0.01}Cu_{0.38}Sb, the ball milling speed was set to 1725 r/min, and 2 large stainless steel balls and 4 small stainless steel balls were added to ensure that the alloy powder achieved the ideal particle size and uniformity.

In the sintering step, the ball-milled powder was loaded into a graphite mold with an inner diameter of 12.7 mm and subjected to spark plasma sintering (SPS) in the glove box. The sintering temperature was set to 700° C., the pressure was 50 MPa, and the time was 5 minutes. During this treatment, the stability of the sintering temperature and pressure was strictly controlled to ensure that the formed material was in a good crystal structure.

The resistivity and Seebeck coefficient were tested using professional testing equipment and methods within the corresponding temperature range. The results obtained were consistent with the material performance characteristics described in the present disclosure. That is, within a wide temperature range, the resistivity shows a linear temperature dependence, the Seebeck coefficient shows a maximum value of 226 μV/K, and the zT value reaches a maximum of 1.1.

### Embodiment 3

The raw materials were prepared with the composition of TiFe_{0.68}Ru_{0.02}Cu_{0.4}Sb, and an alloy ingot was prepared by arc-melting: the arc-melting treatment was carried out on a water-cooled copper hearth under Ar protective atmosphere, the arc-melting current was 80 mA, and the time was 20 s. After one arc-melting was completed, the ingot was turned over and re-melted four times, the uniformity was checked and an appropriate amount of additional Sb was added, and the amount of addition was adjusted according to the actual situation.

During ball milling, the alloy ingot was placed in a stainless steel ball milling jar and was ball milled using a SPEX 8000 M mixer in an Ar atmosphere glove box. According to the characteristics of TiFe_{0.68}Ru_{0.02}Cu_{0.4}Sb, the ball milling speed was set to 1725 r/min, and 2 large stainless steel balls and 4 small stainless steel balls were added to ensure that the alloy powder achieved the ideal particle size and uniformity.

In the sintering step, the ball-milled powder was loaded into a graphite mold with an inner diameter of 12.7 mm and subjected to spark plasma sintering (SPS) in the glove box. The sintering temperature was set to 700° C., the pressure was 50 MPa, and the time was 5 minutes. During this treatment, the stability of the sintering temperature and pressure was strictly controlled to ensure that the formed material was in a good crystal structure.

The resistivity and Seebeck coefficient were tested using professional testing equipment and methods within the corresponding temperature range. The results obtained were consistent with the material performance characteristics described in the present disclosure. That is, within a wide temperature range, the resistivity shows a linear temperature dependence, the Seebeck coefficient shows a maximum value of 217 μV/K, and the zT value reaches a maximum of 1.04.

### Embodiment 4

The process of the present embodiment was substantially the same as that of Embodiment 2, except that the raw materials were prepared with a composition of TiFe_{0.68}Ru_{0.03}Cu_{0.42}Sb.

The resistivity and Seebeck coefficient were tested using professional testing equipment and methods within the corresponding temperature range. The results obtained were consistent with the material performance characteristics described in the present disclosure. That is, within a wide temperature range, the resistivity shows a linear temperature dependence, the Seebeck coefficient shows a maximum value of 212 μV/K.

### Embodiment 5

The process of the present embodiment was substantially the same as that of Embodiment 1, except that the raw materials were prepared with a composition of TiFe_{0.75}Cu_{0.5}Sb.

The resistivity and Seebeck coefficient were tested using professional testing equipment and methods within the corresponding temperature range. The results obtained were consistent with the material performance characteristics described in the present disclosure. That is, within a wide temperature range, the resistivity shows a linear temperature dependence, the Seebeck coefficient shows a maximum value of 183 μV/K.

### Embodiment 6

The process of the present embodiment was substantially the same as that of Embodiment 1, except that the raw materials were prepared with a composition of TiFe_{0.7}Cu_{0.4}Sb.

The resistivity and Seebeck coefficient were tested using professional testing equipment and methods within the corresponding temperature range. The results obtained were consistent with the material performance characteristics described in the present disclosure. That is, within a wide temperature range, the resistivity shows a linear temperature dependence, the Seebeck coefficient shows a maximum value of 196 μV/K.

### Embodiment 7

The process of the present embodiment was substantially the same as that of Embodiment 1, except that the raw materials were prepared with a composition of TiFe_{0.69}Cu_{0.38}Sb.

The resistivity and Seebeck coefficient were tested using professional testing equipment and methods within the corresponding temperature range. The results obtained were consistent with the material performance characteristics described in the present disclosure. That is, within a wide temperature range, the resistivity shows a linear temperature dependence, the Seebeck coefficient shows a maximum value of 214 μV/K.

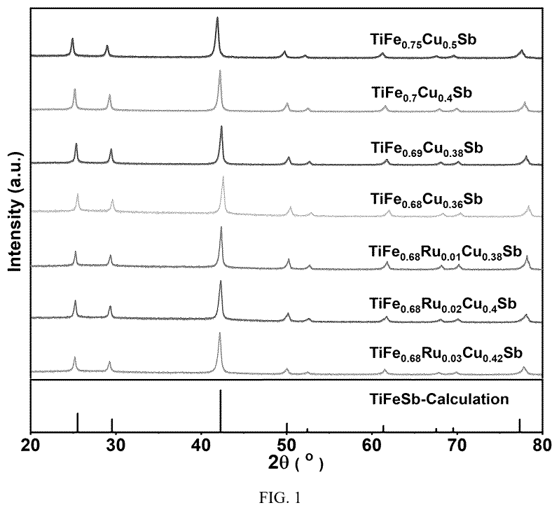

FIG. 1 is an XRD diagram of the thermoelectric materials prepared in Embodiments 1-7 according to the present disclosure.

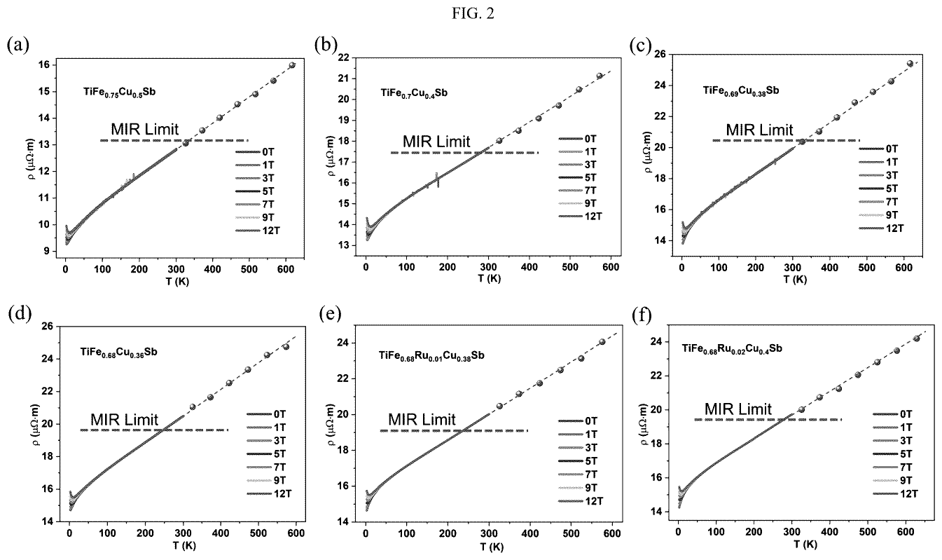

FIG. 2 is a graph showing resistivity versus temperature curves of the thermoelectric materials prepared in embodiments 1-6 according to the present disclosure.

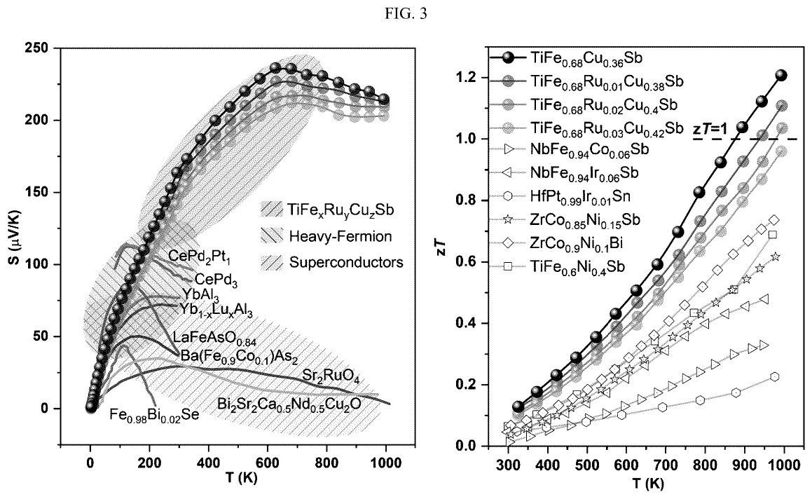

FIG. 3 is a graph showing Seebeck coefficient and zT value versus temperature curves of the thermoelectric materials prepared in embodiments 1 to 4 according to the present disclosure and other thermoelectric materials.

It should be understood that the application of the present disclosure is not limited to the above embodiments. For those skilled in the art, improvements or substitutions can be made based on the above description. All these improvements and substitutions should fall within the scope of protection of the claims attached to the present disclosure.

1-10. (canceled)

11. An unconventional thermoelectric material, wherein a chemical formula of the unconventional thermoelectric material is TiFeₓRu_{y}Cu_{z}Sb, wherein x, y, z are molecular weights of Fe, Ru, and Cu in the chemical formula, respectively, 1<x+y+z<2, and x and z are not 0.

12. The unconventional thermoelectric material according to claim 11, wherein the chemical formula of the unconventional thermoelectric material is one of TiFe_{0.68}Ru_{0.01}Cu_{0.38}Sb, TiFe_{0.68}Ru_{0.02}Cu_{0.4}Sb, TiFe_{0.68}Ru_{0.03}Cu_{0.42}Sb, TiFe_{0.68}Cu_{0.36}Sb, TiFe_{0.69}Cu_{0.38}Sb, TiFe_{0.7}Cu_{0.4}Sb, and TiFe_{0.75}Cu_{0.5}Sb.

13. The unconventional thermoelectric material according to claim 11, wherein a Seebeck coefficient of the unconventional thermoelectric material is greater than 180 μV/K, and a zT value of the unconventional thermoelectric material is greater than 1.0.

14. A preparation method for the unconventional thermoelectric material according to claim 11, comprising steps of:
weighing raw materials; and
processing the raw materials with an arc-melting treatment, ball milling treatment, and spark plasma sintering treatment sequentially, to obtain the unconventional thermoelectric material.

15. The preparation method according to claim 14, wherein steps of processing the raw materials with the arc-melting treatment comprise: placing the weighed raw materials on a water-cooled copper hearth under inert gas protection, setting a melting current to 50-120 mA and a melting time to 5-40 seconds, and completing the arc-melting to obtain an alloy ingot.

16. The preparation method according to claim 15, wherein, during the arc-melting treatment, a raw material of Sb is added to the water-cooled copper hearth to compensate for a weight loss due to high vapor pressure.

17. The preparation method according to claim 14, wherein, after each arc-melting treatment, the alloy ingot is turned over and re-melted 2-8 times.

18. The preparation method according to claim 15, wherein steps of the ball milling treatment comprise: ball milling the alloy ingot at a rotation speed of 1400-2000 r/min for 6-120 minutes to obtain alloy powder.

19. The preparation method according to claim 18, wherein the ball milling treatment is carried out under inert gas protection.

20. The preparation method according to claim 18, wherein steps of the spark plasma sintering treatment comprise: spark plasma sintering the alloy powder at a temperature of 600-800° C. and a pressure of 30-60 MPa for 2-15 minutes.
